(19) United States
(12) Patent Application Publication
(10) Pub. No.: US 2025/0157821 A1
(43) Pub. Date: May 15, 2025

(54) BACKSIDE IMPLANT FOR WAFER CURVATURE CONTROL

(71) Applicant: Axcelis Technologies, Inc., Beverly, MA (US)

(72) Inventors: Sean Jones, Medford, MA (US); Atul Gupta, Lexington, MA (US)

(21) Appl. No.: 18/948,701

(22) Filed: Nov. 15, 2024

Related U.S. Application Data
(60) Provisional application No. 63/599,118, filed on Nov. 15, 2023.

(51) Int. Cl. H01L 21/265; H01J 37/304; H01J 37/317; H01L 21/302; H01L 21/687

(52) U.S. Cl. CPC H01L 21/26593; H01L 21/687; H01J 37/304; H01J 37/3171; H01L 21/302

(57) ABSTRACT

A method for controlling workpiece deformation presents a first side of a first workpiece having an initial planarity to a first ion beam. The first ion beam deforms the first workpiece to define a first deformation of the first workpiece. A second side of the first workpiece is presented to a second ion beam to define a second deformation of the first workpiece that generally counteracts the first deformation of the first workpiece to define a final planarity of the first workpiece. The first workpiece can be a donor workpiece that is annealed after being presented to the second ion beam to define a split layer on one or more of the first and second sides of the donor workpiece. A receiver workpiece is bonded to the donor workpiece and is split from the donor workpiece to define an engineered substrate.

### REFERENCE TO RELATED APPLICATIONS

This application claims the benefit of U.S. Provisional Application Ser. No. 63/599,118, filed Nov. 15, 2023, entitled, “BACKSIDE IMPLANT FOR WAFER CURVATURE CONTROL”, the contents of all of which are herein incorporated by reference in their entirety.

### FIELD OF THE INVENTION

The present invention relates generally to ion implantation systems, and more specifically to a system and method for controlling a deformation of a workpiece undergoing ion implantation.

### BACKGROUND OF THE INVENTION

In semiconductor processing, a workpiece such as a silicon carbide (SiC) wafer can be prone to deformation associated with various processes performed on the workpiece. Such deformation can include a bowing and/or a warping of the workpiece, whereby bowing is generally defined as being radially symmetric about the workpiece. The bowing can be caused by non-uniform stresses associated with one or more surfaces of the workpiece, such as non-uniform stress between a front surface of the workpiece and a back surface of the workpiece. Bowing can also result from a radial non-uniformity in stress associated with the one or more surfaces of the workpiece. Such stresses can be internal to the workpiece, or can be induced (e.g., thermally induced due to temperature differences across the surface of the workpiece). Warping is a less-specific deformation of the workpiece than bowing, whereby warping generally refers to non-radially symmetric deformation of the workpiece. Asymmetric warp, for example, can be caused by an extreme stress differential between the front surface and back surface of the workpiece, or by a non-uniform stress on a surface of the workpiece.

Stresses in the workpiece can arise from a number of sources, such as mechanical polishing, film growth/application, and ion implantation, and can be considered as being internal or intrinsic stresses due to a modification of material properties (e.g., modulus of elasticity) associated with the workpiece. Stresses in the workpiece can also be introduced during processing of the workpiece due to non-uniformities (e.g., temperature variations) across the surface of the workpiece. FIGS. 1A-1B, for example, illustrate various stages of an ion implantation process performed on a workpiece 10. As illustrated in FIG. 1A, the workpiece 10 is positioned on a chuck 12 that is configured to support the workpiece, wherein the workpiece is initially planar with respect to a clamping surface 14 of the chuck. Once positioned on the chuck 12 and sufficiently clamped thereto, the workpiece 10 may be exposed to an ion beam 16 during an ion implantation process, as illustrated in FIG. 1B, whereby the ion implantation process creates or otherwise induces stresses in the workpiece 10 that are associated with damage to a crystalline lattice 18 associated with a front surface 20 (e.g., also called a top surface, a front side, or a top side) of the workpiece. The stresses in the workpiece 10 thus induce a bow 22 in the workpiece, whereby the workpiece is no longer planar with respect to the clamping surface 14. The bow 22, shown as a concave curvature of the workpiece 10 towards the chuck 12, can further increase as the crystalline lattice 18 of the workpiece is increasingly damaged from the exposure to the ion beam 16. Such stress and damage to the crystalline lattice 18 of the workpiece 10 is seen most notably in high dose ion implantations into the workpiece.

The bow 22 in the workpiece 10 can present issues during subsequent handling and processing of the workpiece. Conventionally, attempts have been made to control bowing of the workpiece 10 by minimizing the damage induced in the crystalline lattice 18 associated with the front surface 20 of the workpiece, or controlling a temperature at which the ion implantation is performed. Ion implantations performed at approximately room temperature (so called room temperature implants), for example, can result in a workpiece exhibiting a greater amount of bowing following an anneal than a workpiece implanted with ions at elevated temperatures (so-called hot implants).

### SUMMARY

The present disclosure thus provides a system and method for controlling a curvature of a workpiece associated with an exposure of the workpiece to an ion beam. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one exemplary aspect of the present disclosure, a method is provided for controlling workpiece deformation associated with an ion implantation. In one example, the method comprises providing a first workpiece having an initial planarity and presenting a first side of the first workpiece to a first ion medium, such as an ion beam or other source of ions. The first ion medium deforms the first workpiece to define a first deformation of the workpiece. Further, a second side of the first workpiece is presented to a second ion medium, such as another ion beam or another source of ions, wherein the second ion medium deforms the first workpiece to define a second deformation of the first workpiece. The first ion beam and second ion medium can be similar or different from one another. Accordingly, the second deformation generally counteracts the first deformation of the first workpiece to define a final planarity of the first workpiece, wherein in one example, the final planarity of the first workpiece approximates the initial planarity of the first workpiece.

In one example, one or more implant conditions associated with each of the first ion medium and the second ion medium are further controlled. For example, the first ion medium can comprise a first ion beam, and the second ion medium can comprise a second ion beam, wherein the one or more implant conditions comprise one or more of an extraction energy, an implant species, a dose, an implant energy, and an angle associated with the respective first ion beam and the second ion beam.

In another example, presenting the second side of the first workpiece to the second ion medium comprises inverting the first workpiece via an inversion apparatus. For example, one or more sides of the first workpiece are selectively gripped and the first workpiece is mechanically rotated about one or more axes.

In still another example, the second side of the first workpiece can comprise a sacrificial layer, and wherein the method further comprises removing the sacrificial layer from the second side of the first workpiece after the second side of the first workpiece is presented to the second ion medium.

In accordance with another aspect of the disclosure, the first workpiece can comprise a donor workpiece having the initial planarity, wherein the first ion medium implants ions into the first side of the donor workpiece, and wherein the second ion medium implants ions into the second side of the donor workpiece. Accordingly, the method can further comprise annealing the donor workpiece after being implanted by the first and second ion mediums, thereby defining a split layer on one or more of the first side and the second side of the donor workpiece. The donor workpiece can be smoother to a predetermined roughness, and a first receiver workpiece can be bonded to the first side of the donor workpiece.

Subsequently, the first receiver workpiece can be split from the donor workpiece to define a first engineered substrate for subsequent semiconductor processing. In another example, a second receiver workpiece can be bonded to the second side of the donor workpiece, and the second receiver workpiece can be split from the donor workpiece to define a second engineered substrate for subsequent semiconductor processing.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1A is a front elevation view of a workpiece positioned on a workpiece support in preparation for a conventional ion implantation.

FIG. 1B is a front elevation view of a bowing of the workpiece of FIG. 1A after the conventional ion implantation is performed.

FIG. 2 is a block diagram schematic of an ion implantation system in accordance with various examples of the present disclosure.

FIG. 3A is a front elevation view of a workpiece positioned on a workpiece support in accordance with various examples of the present disclosure.

FIG. 3B is a front elevation view of the workpiece of FIG. 3A undergoing a first ion implantation on a first side in accordance with various examples of the present disclosure.

FIG. 3C is a front elevation view of the workpiece of FIG. 3B having a first bow in accordance with various examples of the present disclosure.

FIG. 3D is a front elevation view of the workpiece of FIG. 3C in an inverted position on the workpiece support in accordance with various examples of the present disclosure.

FIG. 3E is a front elevation view of the workpiece of FIG. 3D undergoing a second ion implantation on a second side in accordance with various examples of the present disclosure.

FIG. 3F is a front elevation view of the workpiece of FIG. 3E having a second bow having undergone the second ion implantation on the second side in accordance with various examples of the present disclosure.

FIG. 3G is a front elevation view of the workpiece of FIG. 3F having a substantially planar surface in accordance with various examples of the present disclosure.

FIG. 4 is a flow diagram of a methodology for controlling a distortion of a workpiece in accordance with various examples of the present disclosure.

FIG. 5 is a flow diagram of a methodology for controlling a distortion of a workpiece undergoing bonding and splitting in accordance with various examples of the present disclosure.

FIG. 6 is a schematic flow diagram of a methodology for controlling a distortion of a workpiece undergoing bonding and splitting in accordance with various examples of the present disclosure.

FIG. 7 is a flow diagram of a methodology for controlling a distortion of workpieces undergoing bonding and splitting in accordance with further various examples of the present disclosure.

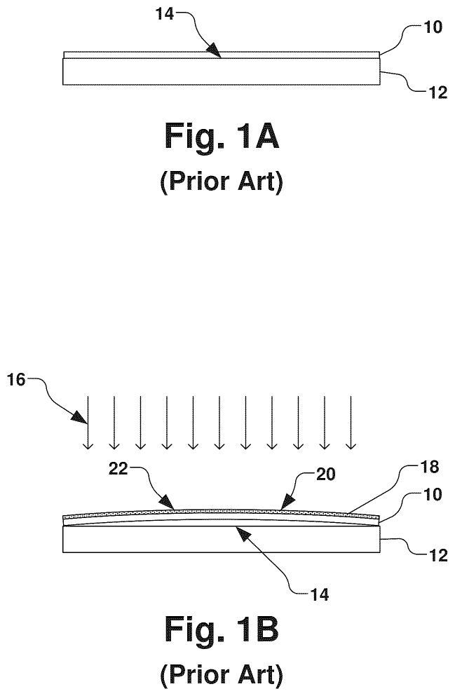

### DETAILED DESCRIPTION OF THE INVENTION

The present disclosure provides a semiconductor processing system and method for controlling a curvature of a workpiece associated with an exposure of the workpiece to a process medium, such as an ion beam. Accordingly, the present invention will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment and may also or alternatively be fully or partially implemented in a common feature or circuit in another embodiment. For example, several functional blocks may be implemented as software running on a common processor, such as a signal processor. It is further to be understood that any connection which may be described as being wire-based in the following specification may also be implemented as a wireless communication, unless noted to the contrary.

The present disclosure appreciates that bowing of a workpiece undergoing semiconductor processing can lead to various issues during subsequent handling and processing of the workpiece. In particular, in conventional ion implantation processing, ions are typically implanted into an implant surface of a first side of the workpiece, thus potentially leading to bowing of the workpiece due to stresses induced by the ion implantation. For example, stresses can be induced in the workpiece due to changes in material properties that occur only in a surface volume of a material of the workpiece that is impacted by the ions during the implantation process. The resulting difference in material properties between the implant surface and surfaces or portions of the of the workpiece that are not implanted with ions can result in a deformation of a shape or surface of the workpiece. For example, a deformation of the workpiece from an initially-planar surface prior to ion implantation to a non-planar surface after ion implantation can result in a bowed or warped surface of the workpiece. Such a non-planar surface of the workpiece can present significant processing challenges in semiconductor manufacturing. It is therefore desirable to mitigate such deformation associated with ion implantation processing. Accordingly, the present disclosure advantageously mitigates bowing of the workpiece by further implanting ions into a second side of the workpiece, wherein the second side is opposite to the first side of the workpiece, thereby counteracting the bowing induced in the first side and providing an increased efficiency of the ion implantation system.

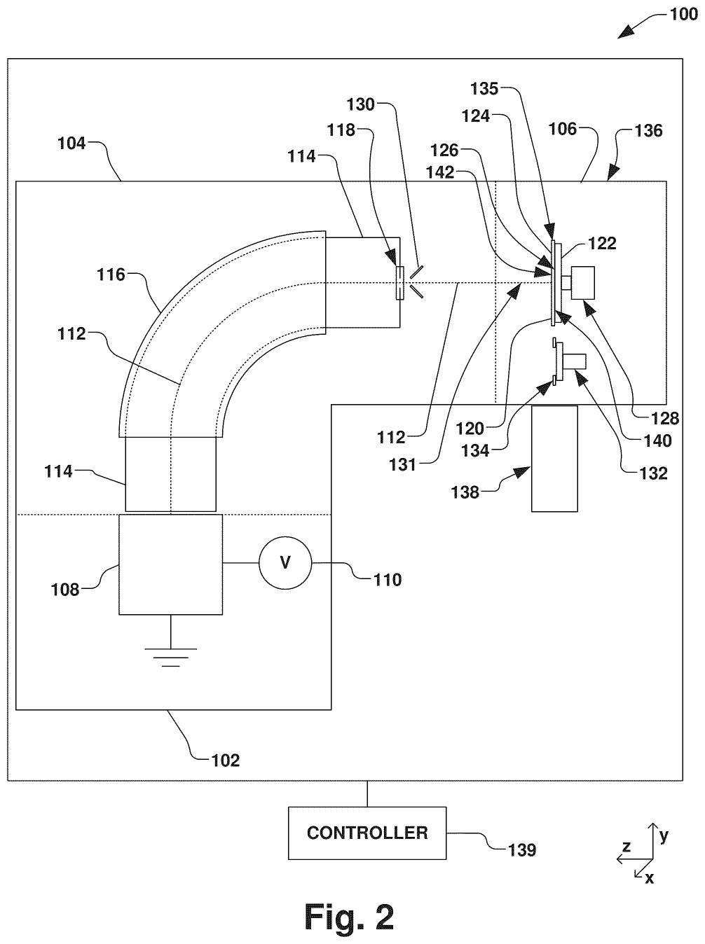

In order to gain a better understanding of the disclosure, referring now to the Figures, FIG. 2 illustrates an ion implantation system 100 in accordance with various example of aspects of the present disclosure. The ion implantation system 100 is illustrated having a terminal 102, a beamline assembly 104, and an end station 106. The terminal 102, for example, comprises an ion source 108 powered by a high voltage power supply 110. The ion source produces and directs an ion beam 112 through the beamline assembly 104, and ultimately, to the end station 106. The ion beam 112, for example, can take the form of a spot beam, pencil beam, ribbon beam, or any other shaped beam. The beamline assembly 104 further has a beam guide 114 and a mass analyzer 116, whereby a dipole magnetic field is established to pass only ions of appropriate charge-to-mass ratio through an aperture 118 at an exit end of the beam guide to a workpiece 120 positioned on a workpiece support 122 in the end station 106. The workpiece 120, such as a silicon carbide (SiC) wafer 124, may be supported on a support surface 126 of the workpiece support 122 (e.g., an electrostatic chuck or ESC, a mechanical gripper, or other support or clamping apparatus). The workpiece support 122 may be further operably coupled to a workpiece scanning apparatus 128 (e.g., a robot) that is configured to scan otherwise translate the workpiece 120 relative to the ion beam 112. Alternatively, or in addition, or the ion beam 112 may be scanned with respect to the workpiece 120 via a beam scanning apparatus 130 (e.g., an electrostatic scanner).

It is to be appreciated that while the ion implantation system 100 is illustrated as one example, other ion implantation systems are also contemplated as falling within the scope of the present disclosure. For example, while not shown, one such ion implantation system can more simply comprise an ion source, an extraction apparatus configured to extract ions from the ion source, and an acceleration apparatus configured to accelerate the ions to higher energy levels toward a process chamber in which the workpiece is positioned for receiving the ions. In other examples, the ion implantation system can comprise a plasma doping system, a plasma shower system, or any other system configured to expose the workpiece to ions. As such, is it to be understood that while various references to the ion beam 112 are described in one example as being a collection of energized ions directed towards the workpiece, the ion beam discussed herein can be alternatively interpreted as an exposure of the workpiece to any ion medium 131 comprising ions, whereby the ion medium can take any shape or form (e.g., an ion beam, a plasma comprising ions, or any other process medium comprising ions). Further, while in the example shown in FIG. 2, the workpiece 120 and the ion beam 112 may be scanned with respect to one another, the present disclosure further contemplates other ion implantation systems (e.g., a plasma doping system—not shown), whereby the workpiece is maintained on a stationary platen and immersed in a plasma of ions that are directly extracted from an ion source and directed towards an entirety of the surface of the workpiece via an electrical bias applied to the workpiece.

Further, in accordance with the present disclosure, a workpiece inversion apparatus 132 is provided, whereby the workpiece inversion apparatus can be configured to selectively position the workpiece 120 with respect to the support surface 126 of the workpiece support 122. As will be discussed in greater detail infra, the workpiece inversion apparatus 132 can be configured to selectively translate and/or rotate the workpiece 120 with respect to one or more of the x-axis, y-axis, or z-axis. For example, the workpiece inversion apparatus 132 can comprise any number of linear actuators, rotary actuators, or other automated actuators, such as a robot. The workpiece inversion apparatus 132, for example, further comprises one or more end effectors 134 (e.g., a gripping apparatus), wherein the one or more end effectors are configured to selectively secure, grip, or hold the workpiece 120 concurrent with the selective translation and/or rotation of the workpiece.

In one example, while not shown, the workpiece 120 may be positioned in a workpiece holder, whereby the one or more end effectors 134 are configured to secure, grip, or hold the workpiece holder. It is to be further appreciated that while the present disclosure contemplates individual processing of the workpiece 120, batch processing of multiple workpieces is further contemplated, whereby a plurality of workpieces may be concurrently supported and exposed to the ions, as well as selectively positioned with respect to the ion beam 112 (or other plasma of ions). For example, the present disclosure further contemplates the ion beam 112 being stationary, whereby the plurality of workpieces can be supported on a disc that is rotated and translated through the ion beam, and whereby the workpiece inversion apparatus 132 can be further configured to invert the plurality of workpieces.

The one or more end effectors 134 of the workpiece inversion apparatus 132, for example, can be configured to perform one or more functions such as gripping the workpiece 120 from an edge or side 135 thereof, lifting the workpiece from the workpiece support 122 or other processing station (not shown), rotating the workpiece by 180 degrees to invert the workpiece, and placement of the workpiece back on the workpiece support or other processing station. The one or more functions performed by the one or more end effectors 134, for example, can be performed in-situ (e.g., within the end station 106), whereby multiple sides of the workpiece 120 can be implanted (e.g., generally referred to as double-sided processing, described infra), while the workpiece remains within the end station.

One or more of the workpiece scanning apparatus 128 or the workpiece inversion apparatus 132, for example, can be further configured to selectively transfer the workpiece 120 between a process chamber 136 in which the workpiece is implanted by the ion beam 112 and a load lock chamber 138 operably coupled to the process chamber. Alternatively, while not shown a transfer apparatus may be provided to selectively transfer the workpiece 120 between the process chamber 136 and the load lock chamber 138. A controller 139, for example, is further provided and configured to control any of the various components of the ion implantation system 100 illustrated in FIG. 2, such as one or more of the workpiece inversion apparatus 132, the one or more end effectors 134 and the workpiece scanning apparatus 128, whereby the controller can be configured to control a position of the workpiece 120 with respect to the ion beam 112.

The present disclosure appreciates that the implantation of ions from the ion beam 112 into the workpiece 120 may lead to bowing of the workpiece, particularly when the workpiece comprises the SiC wafer 124 discussed above. Absent countermeasures, such bowing of the workpiece 120 may lead to subsequent processing and/or handling errors within the ion implantation system 100 or in other processing. Accordingly, the workpiece inversion apparatus 132 of the present disclosure can be configured to selectively rotate the workpiece 120 with respect to the support surface 126 of the workpiece support 122, such as by selectively rotating the workpiece about one or more of the x-axis and the y-axis. The workpiece inversion apparatus 132 and the one or more end effectors 134, for example, are thus configured to selectively grip the workpiece 120, and to selectively remove the workpiece from the support surface 126 of the workpiece support 122. The workpiece inversion apparatus 132 and the one or more end effectors 134 of the present example are further configured to selectively rotate the workpiece 120 with respect to the support surface 126 of the workpiece support 122, and to selectively re-position the workpiece on the support surface, whereby a plurality of surfaces or sides of the workpiece may be selectively exposed to the ion beam 112 for exposure thereto. As such, the plurality of surfaces of the workpiece 120 may be selectively exposed to the ion beam 112, as will now be discussed.

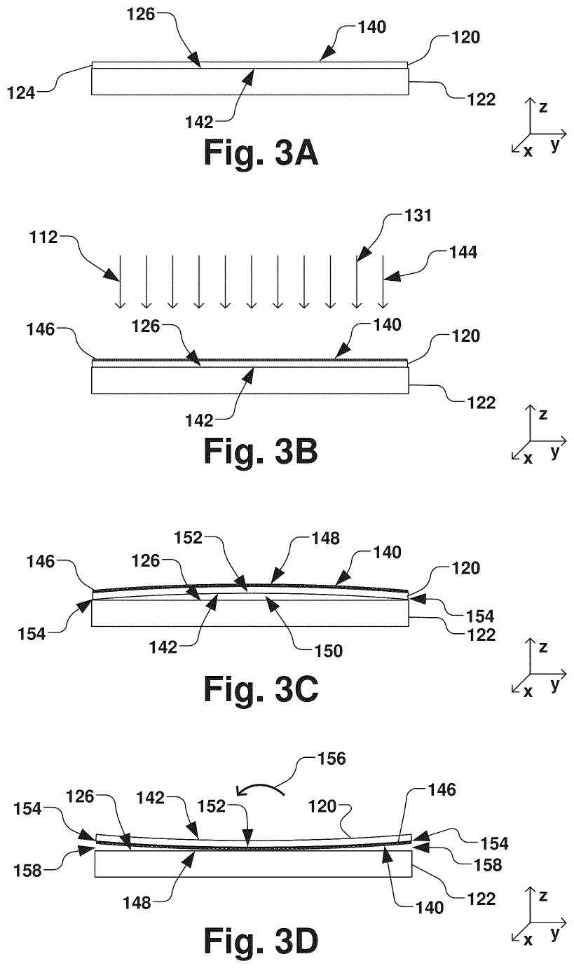

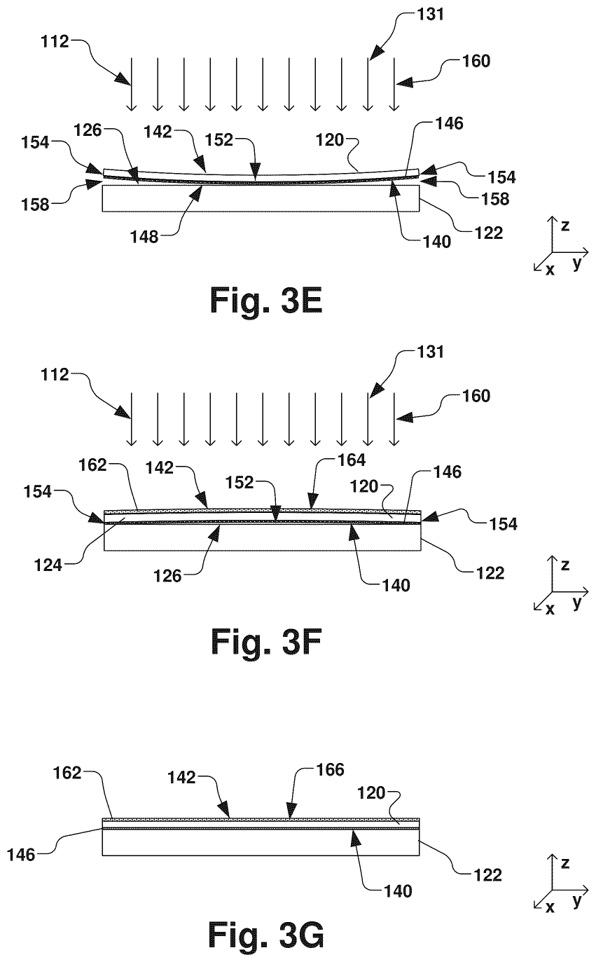

FIG. 3A, for example, illustrates the workpiece 120 positioned on the workpiece support 122, whereby the workpiece is defined by a first surface 140 (e.g., a backside) and a second surface 142 (e.g., a front side), wherein the first surface is opposite the second surface. In the present example, the second surface 142 of the workpiece faces the support surface 126 of the workpiece support 122. The second surface 142 in the present example is generally co-planar with the support surface 126 of the workpiece support 122, whereby at least a portion of the workpiece 120 can be in contact with, and generally supported by, the support surface of the workpiece support.

As illustrated in FIG. 3B, while positioned on the workpiece support 122, the first surface 140 of the workpiece 120 is exposed to a first ion implantation 144 from the ion beam 112 to define a first implantation layer 146 in the workpiece. The configuration of the ion beam 112 for the first ion implantation 144 (e.g., a low-dose unchanneled implant), for example, induces stresses and damage in the lattice of the first implantation layer 146 of workpiece 120, thus leading to a first bow 148 (e.g., a first deformation) in the workpiece, as illustrated in FIG. 3C. Implantation parameters or one or more implant conditions associated with first ion implantation 144 can be configured to maximize damage to the first implantation layer 146, whereby the first bow 148 in the workpiece 120, for example, generally defines a center gap 150 between a center portion 152 of the workpiece and the support surface 126, while a periphery 154 of the workpiece generally remains in contact with the support surface. The first ion implantation 144, for example, may be configured to induce the first bow 148 such that the first bow is configured to mitigate or compensate for subsequent bowing of the workpiece in subsequent ion implantations, as will be described infra. It should be noted that FIG. 3C is not necessarily drawn to scale, and that the first bow 148 and the center gap 150 can be of various sizes.

In accordance with one example, the present disclosure contemplates the first bow 148 (also called a compensatory bow) in the workpiece 120 induced by the first ion implantation 144 (also called a compensatory implant) of FIG. 3B as serving to mitigate bowing in the workpiece associated with ions that may be implanted into the second surface 142 of the workpiece. As such, the present disclosure contemplates an inversion 156 (illustrated by arrow) of the workpiece 120 is shown in FIG. 3D, whereby the workpiece is inverted or otherwise rotated (e.g., rotated about the x-axis or y-axis) such that the first surface 140 of the workpiece is positioned facing the support surface 126 of the workpiece support 122. As such, the center gap 150 shown in FIG. 3C between the workpiece 120 and the support surface 126 is generally eliminated in FIG. 3D, while a peripheral gap 158 may be seen at the periphery 154 of the workpiece after the inversion 156. The inversion 156, for example, can be performed by the workpiece inversion apparatus 132 and the one or more end effectors 134 shown in FIG. 2.

In accordance with the present disclosure, as illustrated in FIG. 3E, for example, while the workpiece 120 is positioned on the workpiece support 122 with the first surface 140 facing the support surface 126, the second surface 142 of the workpiece is exposed to a second ion implantation 160 from the ion beam 112. As such, the second ion implantation 160 defines a second implantation layer 162 in the workpiece, as illustrated in FIG. 3F. In one example, the second ion implantation 160 can be configured in a manner similar to the first ion implantation 144 of FIG. 3B. In another example, the ion beam 112 can be configured such that the second ion implantation 160 of FIG. 3F provides a high-dose implant that is performed on the workpiece 120 (e.g., the SiC wafer 124), whereby the second ion implantation performed on the second surface 142 of the workpiece generally induces a second bow 164 (e.g., a second deformation) in the workpiece. The present disclosure contemplates one or more of the first ion implantation 144 of FIG. 3B and the second ion implantation 160 of FIG. 3F being performed at various temperatures, such as at approximately room temperature, or at an elevated temperature that may be appropriate for a high dose implant. The second ion implantation 160 into the second surface 142 of the workpiece 120, for example, is generally considered a process implant, whereby various semiconductor devices (not shown) are formed on, or associated with, the second surface in other semiconductor processing performed on the workpiece

In accordance with the present disclosure, the second bow 164 in the workpiece 120, for example, is generally counteracted or otherwise mitigated by the first bow 148 (e.g., the compensatory bow) of FIG. 3C, whereby the second bow has substantially less curvature than the first bow. Accordingly, the first ion implantation 144 (e.g., the compensation implant) into the first surface 140 of the workpiece 120 of FIG. 3B thus compensates for and/or reduces the curvature resulting from the second bow 164 from the second ion implantation 160 of FIG. 3F. Again, the second bow 164 shown in FIG. 3F is not drawn to scale, and various implant conditions associated with the second ion implantation 160, can thus provide a greater planarity of the first surface 140 and the second surface 142. The implant conditions of the first ion implantation 144 of FIG. 3B and the implant conditions of the second ion implantation 160 of FIG. 3F, such as an implant species, a dose, an extraction energy, an implant energy, and an angle of one or more of the first ion implantation and the second ion implantation, for example, can be tuned to produce a minimal curvature associated with the second bow 164. It is further noted that the order to the first ion implantation 144 of FIG. 3B and the second ion implantation 160 of FIG. 3F may be reversed, whereby the second ion implantation is performed prior to the first ion implantation. The dose of one or more of the first ion implantation 144 of FIG. 3B and the second ion implantation 160 of FIG. 3F, for example, can be a threshold dose that is selected to achieve a desired shape change of the workpiece 120 that yields a sufficient stress in the implanted layer to result in the desired shape change. While various ranges of the threshold dose are contemplated, in one example, the threshold dose for mitigation of the first bow 148 of FIG. 3C can be configured to vary from a minimum of 1e14 at/cm² to a maximum of 1e17 at/cm².

In some examples, the second bow 164 induced in the workpiece 120 by the second ion implantation 160 of FIG. 3F can produce a substantial planarity 166 associated with the first surface 140 and the second surface 142 of the workpiece, as shown in FIG. 3G. As such, subsequent processing of the workpiece 120 can be substantially unaffected by the second bow 164 produced in FIG. 3F. It is also noted that the present disclosure contemplates the first ion implantation 144 shown in FIG. 3B being performed either before, or after the second ion implantation 160 shown in FIG. 3F, whereby the compensatory bow associated with the first ion implantation counteracts the second bow 164 in either instance, such that the substantial planarity 166 shown in FIG. 3G is achieved.

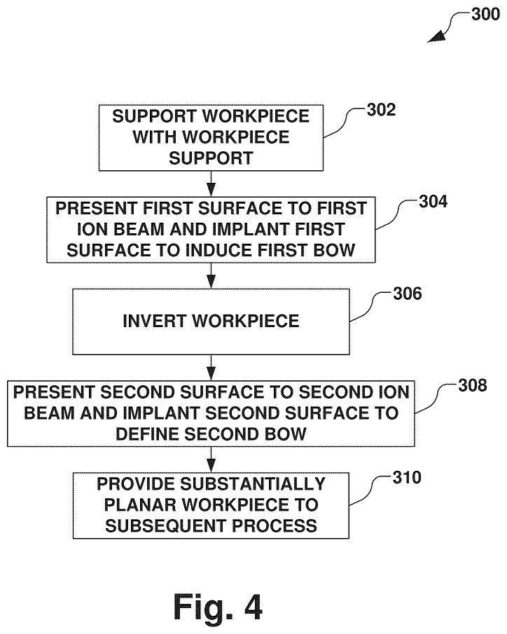

In accordance with various aspects of the present disclosure, FIG. 4 further illustrates a method 300 for controlling a deformation of a workpiece undergoing ion implantation. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 of FIG. 4 begins at act 302, wherein a workpiece (also generically referred to as a first workpiece) is supported on a workpiece support. The workpiece of act 302, for example, may be the workpiece 120 of FIG. 3A that is supported on the workpiece support 122. In act 304 of FIG. 4, a first surface of the workpiece is subjected to a first ion implantation, wherein the first ion implantation induces a first bow in the workpiece. For example, FIG. 3B illustrates the first surface 140 of the workpiece 120 being subjected to the first ion implantation 144, whereby the first bow 148 of FIG. 3C is induced by the first ion implantation.

In act 306 of FIG. 4, the workpiece is inverted with respect to the ion beam or the workpiece support, such that in act 308, the second surface of the workpiece is subjected to a second ion implantation, wherein the second ion implantation induces a second bow in the workpiece. Act 306, for example, is illustrated in FIG. 3D, whereby the workpiece 120 is inverted on the workpiece support 122, and FIGS. 3E-3F further illustrate the workpiece being subjected to the second ion implantation 160, whereby the second bow 164 is induced. Further, in act 310 of FIG. 4, a substantially planar workpiece is thus yielded, whereby the substantially planar workpiece can be provided to subsequent semiconductor processes. The substantially planar workpiece provided in act 310, for example, can comprise the workpiece 120 of FIG. 3G having the substantial planarity 166 associated with the first surface 140 and the second surface 142 of the workpiece.

The ion implantation system 100 of FIG. 2 and method 300 of FIG. 4, for example, thus advantageously implant ions into opposing sides of the workpiece 120 (e.g., the backside or first surface 140 and the frontside or the second surface 142) in order to intentionally induce a compensatory bow in the workpiece to counteract bowing of the workpiece when a process implant is performed on the workpiece. As such, the present disclosure achieves relatively flat or planar surfaces on the opposing sides of the workpiece 120, whereby subsequent processing of the workpiece can be performed without deleterious issues associated with conventional bowing or warping seen in workpieces.

Such double-sided processing of both the first surface 140 and the second surface 142 of the workpiece 120 is contemplated as being particularly useful in applications such as layer transfer, whereby a thin layer of the monocrystalline substrate is spliced off the workpiece after implantation by bonding to a receiver substrate. Such double-sided processing, for example, is further contemplated as allowing for simultaneous, concurrent, or sequential splitting of two layers to two receiver substrates (e.g., one layer from each respective side of a donor workpiece that is implanted on both sides). This approach has an advantage of eliminating some of the process steps in a layer transfer sequence such as annealing of the substrate to form a so-called “bubble layer” below the implanted surface prior to layer transfer, as two transfer layers can be formed with one anneal (e.g., one layer on each surface of the donor workpiece).

The processing of the present disclosure, for example, can comprise the first ion implantation 144 (e.g., a low-dose room-temperature un-channeled implant) to the first surface 140 of SiC wafer 124, whereby the first bow 148 associated therewith is configured to mitigate the second bow 164 of FIG. 3F that may be associated with the second ion implantation 160 (e.g., a high dose implant) to the second surface 142 of the SiC wafer. The present disclosure further contemplates various benefits of the first ion implantation 144 being a room temperature implant, as the benefits of the process may persist through multiple hot implant/anneal processes.

For example, implant conditions such as implant species, dose, implant energy, and angle of the implant associated with the first ion implantation 144 to the first surface 140 of the workpiece 120 of FIG. 3B, for example, can be tuned to compensate for the second bow 164 of the workpiece associated with the second ion implantation 160 to the second surface 142 of FIG. 3F, whereby bowing may be optimized for throughput or other parameters, such as conductivity.

The present disclosure further contemplates the first ion implantation 144 into the first surface 140 of the workpiece 120 being performed directly on the workpiece 120 of FIG. 3B, or into a sacrificial film (not shown) deposited on the first surface of the workpiece. As such, the sacrificial film can be removed subsequent to a formation of devices associated with the second surface 142 of the workpiece 120. Alternatively, the present disclosure contemplates a removal of the first implantation layer 146 of the workpiece 120 shown in FIG. 3G, such as by chemical mechanical polishing (CMP), etching, or other removal techniques, whereby the first implantation layer is removed from the workpiece prior to various final steps in device fabrication.

Additionally, the present disclosure appreciates that a persistence of the first implantation layer 146 can further allow for encapsulation processing (not shown) in order to protect the second surface 142 of the workpiece 120 prior to various ion implantation thereto.

In accordance with another aspect of the present disclosure another methodology for mitigating bowing in a workpiece is contemplated, whereby a deposition of “stressed” films is performed in order to compensate for compressive stress introduced in the implanted layer. Such stressed films, for example, may be removed prior to fabrication of contacts (not shown) associated with the first surface 140 (e.g., the backside) of the workpiece 120 to complete a fabrication of devices such as power MOSFETs and diodes, whereby such devices can have terminals on both the first surface and second surface 142 of the workpiece.

In various examples of the present disclosure, the first ion implantation 144 associated with the first surface 140 (e.g., the backside) of the workpiece 120 of FIG. 3B may not require removal process in a device fabrication sequence. As such, the present disclosure can advantageously reduce the cost of manufacturing. Indeed, the present disclosure further contemplates other advantages, such as implanting a dopant species to the backside of a workpiece such that the implant can be advantageously incorporated into a semiconductor process in order to enhance a conductivity of contacts on the backside of a workpiece in devices such as power MOSFETs and diodes.

It is also noted that the present disclosure further contemplates an elimination of the above-mentioned sacrificial films in device manufacturing, and is further contemplated as enabling double-side processing in various applications, such as layer transfer applications that utilize a so-called donor wafer to remain substantially flat in order to facilitate bonding to a receiver substrate.

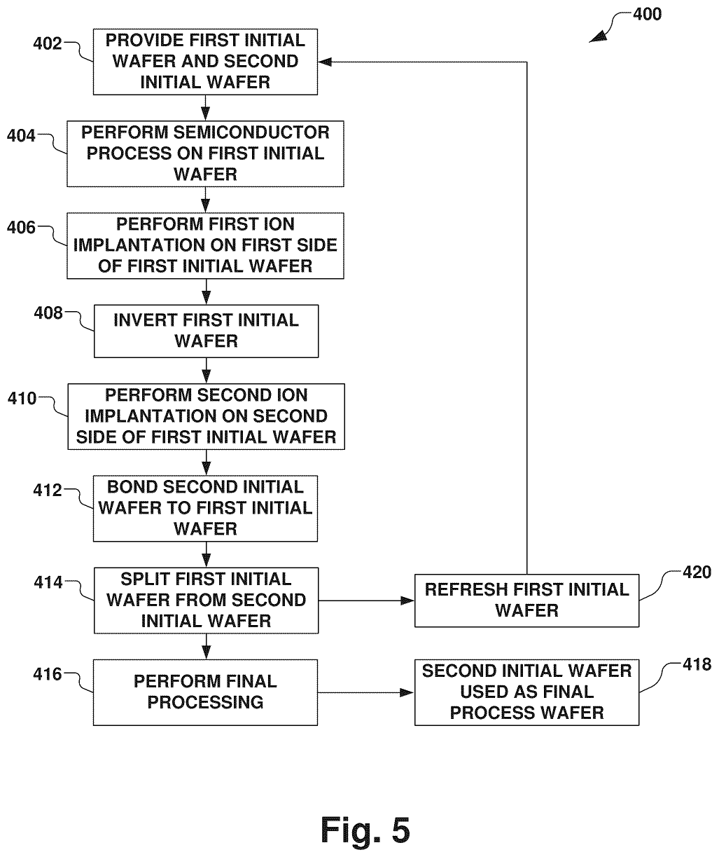

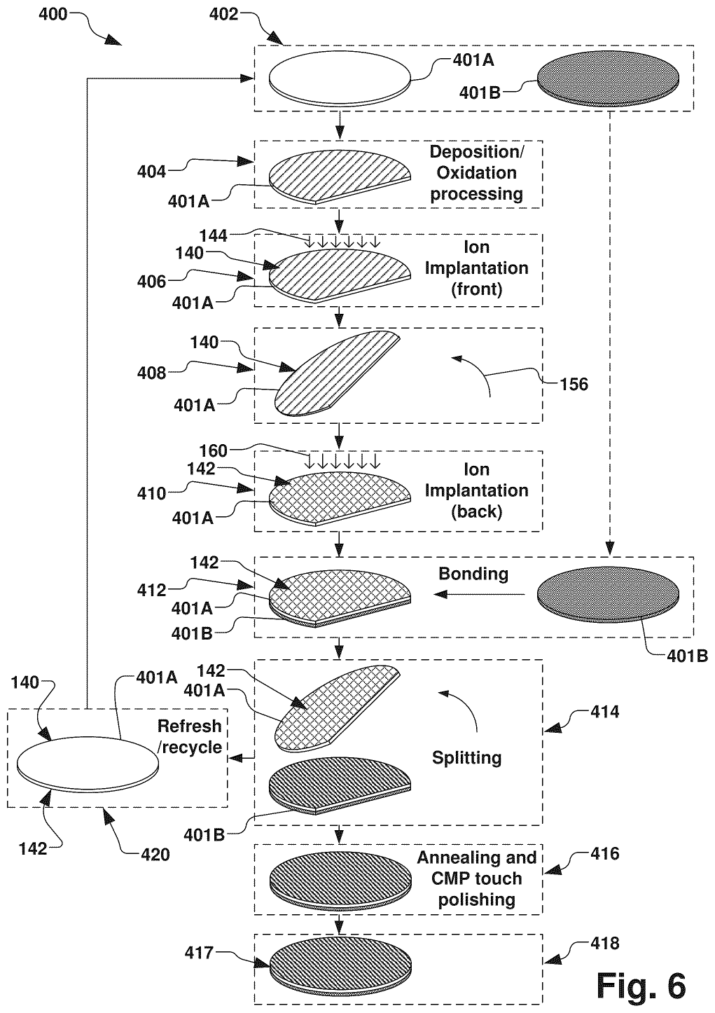

The present disclosure, for example, further contemplates a control of a bowing of workpieces, such as SiC wafers, when the workpieces are utilized in layer transfer applications, also called wafer splitting. Thus, in accordance with various examples of the disclosure, FIG. 5 illustrates a wafer splitting method 400, wherein the method may incorporate the mitigation of bowing of the workpiece by further including the method 300 of FIG. 4, therein. The wafer splitting method 400 of FIG. 5 is further pictorially illustrated in FIG. 6, whereby FIGS. 5-6 will now be jointly referenced. For example, the wafer splitting method 400 of FIGS. 5-6 begins at act 402, whereby a first initial wafer 401A and a second initial wafer 401B shown in FIG. 6 are provided. One or more of the first initial wafer 401A and the second initial wafer 401B, for example, is comprised of a first initial material, such as silicon carbide, and can comprise the SiC wafer 124 of FIG. 3A. In one example, the SiC wafer 124 is initially provided with the first surface 140 and second surface 142 in a polished state and ready for processing.

In act 404 of FIGS. 5-6, one or more semiconductor processes can be performed on the first initial wafer 401A, such as various deposition and oxidation processes that may be performed on one or more surfaces of the first initial wafer. For example, the one or more semiconductor processes can be performed on one or of the first surface 140 or the second surface 142 of the SiC wafer 124 of FIG. 3A. In act 406 of FIGS. 5-6, the first ion implantation 144 is performed on the first surface 140 of the first initial wafer 401A. Act 406, for example, can induce a first bow in the first initial wafer 401A, such as the first bow 148 of FIG. 3C from the first ion implantation 144 shown in FIG. 3B. Accordingly, in act 408 of FIGS. 5-6, the first initial wafer 401A is inverted, whereby in act 410, the second ion implantation 160 is performed on the second surface 142 of the first initial wafer 401A. For example, act 408 is illustrated in by the inversion 156 in FIG. 3D, and the second ion implantation 160 is illustrated in FIG. 3E. It is noted that the method 300 of FIG. 4 can be considered to include acts 404, 406, 408, and 410 of FIGS. 5-6.

In accordance with one example, the second ion implantation 160 into the first initial wafer 401A of FIGS. 5-6 provides a substantially flat surface to enable a bonding of the first initial wafer to the second initial wafer 401B in act 412. In act 414, the first initial wafer 401A is split from the second initial wafer 401B. Final processing of the second initial wafer 401B, for example, is performed in act 416, such as by polishing and cleaning of the second initial wafer. Once the final processing of the second initial wafer 401B is performed in act 416, the second initial wafer can be forwarded for use as a final implanted wafer 417 (also called an engineered substrate) in subsequent semiconductor processing in act 418.

Further, in splitting the first initial wafer 401A from the second initial wafer 401B in act 414 of FIGS. 5-6, the first initial wafer can be further refreshed in act 420, such as by cleaning and/or polishing one or more of the first surface 140 and the second surface 142 of the first initial wafer. Once the first initial wafer 401A is refreshed in act 420, it can be re-used or recycled as the first initial wafer in act 402, and the process may start again with another second initial wafer 401B.

In another exemplary aspect of the disclosure, the wafer splitting method 400 can be implemented for creating one or more splitting layers (also called a split layer) implemented in acts 412 and 414, whereby in one example, the one or more splitting layers are formed on one or more sides of a donor substrate (e.g., a workpiece as described above) via an ion implantation (e.g., a sequential ion implantation) of one or more of H+ and He+ ions, and wherein the ion implantation is performed above a threshold dose on the one or more sides of the donor substrate.

The threshold dose, for example, can provide a clean and complete layer transfer on the donor substrate, and can be a minimum concentration of ions (e.g., H ions or He ions) implanted in the donor substrate that can effectively coalesce (e.g., via Ostwald Ripening), such that a mobile gas layer (also called a gas bubbles) that is formed under the surface of the donor substrate is generally continuous (e.g., having no isolated pockets of gas bubbles). For example, the threshold dose for splitting SiC wafers can be defined as exceeding 1e16 at/cm² and in some examples, can range from 6e16 at/cm²-2e17 at/cm².

Accordingly, the split layer(s) are defined through an annealing process that effectively agglomerates the implanted ions into the mobile gas layer (e.g., through Ostwald ripening). Further, one or more of the first surface and the second surface of the donor substrate can be individually or additionally smoothed to less than approximately 1 nm roughness, such as provided in the final processing of the second initial wafer in act 416 and/or the refreshing of the first initial wafer in act 420.

In another example, one or more receiver substrates (e.g., one or more workpieces as described above) can be respectively bonded to one or more of the first surface and the second surface of the donor substrate. Further, the respective one or more receiver substrates are split from the respective one or more of the first surface and the second surface of the donor substrate, thereby transferring the respective split layer from the donor substrate to the respective one or more receiver substrates. Accordingly, one or more receiver substrates receive the respective split layer from a single donor substrate.

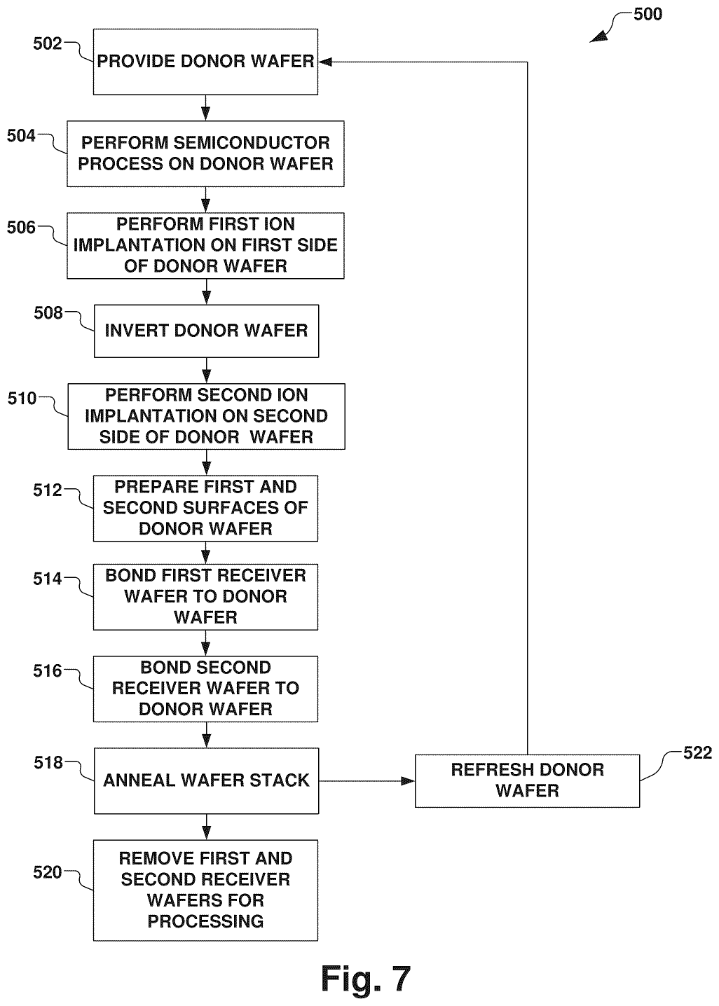

Further, in accordance with yet another exemplary aspect of the disclosure, a double side layer transfer is further contemplated, whereby the potential exists to double the throughput of the wafer splitting in act 414 of FIGS. 5-6, thus reducing the cost of the process and doubling the utilization of the donor substrate. Such an alternative method 500 is illustrated in FIG. 7, whereby in act 502, a donor wafer (e.g., the workpiece 120 of FIG. 3A) can be provided whereby the first surface and the second surface of the donor wafer are polished in act 504. In act 506 of FIG. 7, the first surface of the donor wafer is implanted with H, thus resulting in a first bow of the donor wafer. In act 508, the donor wafer is inverted, and in act 510, the second surface is implanted with H, thus inducing the second bow of the donor wafer and substantially flattening the donor wafer. In act 512, the first surface and the second surface of the donor wafer are cleaned and/or polished in preparation for bonding.

In act 514, a first receiver wafer is bonded to the first surface of the donor wafer, and in act 516, a second received wafer is bonded to the second surface of the donor wafer, thus defining a wafer stack. In act 518, the wafer stack is annealed in order to initiate wafer splitting (e.g., via Ostwald Ripening) on both surfaces, whereby in act 520, the first receiver wafer and the second receiver wafer are removed from the donor wafer and provided as first and second engineered substrates for subsequent processing, whereby the donor wafer is recycled and reprocessed in act 522 for use again in act 502.

It is noted that the present disclosure is contemplated as having applicability outside of the field of ion implantation in other semiconductor device processing tools, as well other industries, etc. for mitigating bowing of workpieces, such as SiC wafers. As such, one of ordinary skill will appreciate that the methodology and teachings provided herein can be applied to various processes, other than ion implantation, and are contemplated as falling within the scope of the present disclosure.

The present disclosure further contemplates providing damage to a workpiece in order to force a slight bow to the workpiece, thus aiding in bow reduction for various steps in further subsequent processes. The present disclosure contemplates implantation of ions into the first side of the workpiece occurring before, and/or after the implantation of ions into the second side of the workpiece. Further, a configuration of one or more parameters of the ion beam may differ between the implantation of ions into the first side and the second side of the workpiece.

The present disclosure contemplates various configurations of ion implantation systems, whereby any of the ion implantation systems can be configured to provide the above-described implantation to both front and back surfaces of a workpiece in order to mitigate bowing, thereof. For example, the present disclosure contemplates any ion implantation system manufactured by Axcelis Technologies, Inc. of Beverley, Mass. being configured to selectively implant the front and back sides of a workpiece, and to control an orientation of the workpiece with respect to an ion beam for such selective implants. The present disclosure contemplates various workpiece positioning apparatuses, such as robotic apparatuses and workpiece handling systems, that are configured to selectively expose both the front and back sides of the workpiece to the ion beam.

Although the invention has been illustrated and described with respect to one or more implementations, it will be understood that alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including any reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method for controlling workpiece deformation, the method comprising:
providing a first workpiece having an initial planarity;
presenting a first side of the first workpiece to a first ion medium, wherein the first ion medium deforms the first workpiece to define a first deformation of the first workpiece; and
presenting a second side of the first workpiece to a second ion medium, wherein the second ion medium deforms the first workpiece to define a second deformation of the first workpiece, wherein the second deformation generally counteracts the first deformation of the first workpiece to define a final planarity of the first workpiece.

2. The method of claim 1, wherein the final planarity of the first workpiece approximates the initial planarity of the first workpiece.

3. The method of claim 1, further comprising controlling one or more implant conditions associated with each of the first ion medium and the second ion medium.

4. The method of claim 3, wherein the first ion medium comprises a first ion beam, and wherein the second ion medium comprises a second ion beam, wherein the one or more implant conditions comprise one or more of an extraction energy, an implant species, a dose, an implant energy, and an angle associated with the respective first ion beam and the second ion beam.

5. The method of claim 1, wherein presenting the second side of the first workpiece to the second ion medium comprises inverting the first workpiece by an inversion apparatus.

6. The method of claim 5, wherein inverting the first workpiece comprises gripping one or more sides of the first workpiece and mechanically rotating the first workpiece about one or more axes.

7. The method of claim 1, wherein the second side of the first workpiece comprises a sacrificial layer, and wherein the method further comprises removing the sacrificial layer from the second side of the first workpiece after the second side of the first workpiece is presented to the second ion medium.

8. The method of claim 1, wherein one or more of presenting the first side of the first workpiece to the first ion medium or presenting the second side of the first workpiece to the second ion medium is performed at approximately room temperature.

9. The method of claim 1, wherein the first workpiece comprises a donor workpiece having the initial planarity, wherein the first ion medium implants ions into the first side of the donor workpiece, and wherein the second ion medium implants ions into the second side of the donor workpiece, wherein the method further comprises:
annealing the donor workpiece, thereby defining a split layer on one or more of the first side and the second side of the donor workpiece;
smoothing the donor workpiece to a predetermined roughness;
bonding a first receiver workpiece to the first side of the donor workpiece; and
splitting the first receiver workpiece from the donor workpiece.

10. The method of claim 9, further comprising:
bonding a second receiver workpiece to the second side of the donor workpiece; and
splitting the second receiver workpiece from the donor workpiece.

11. The method of claim 9, wherein one or more of the first ion medium and the second ion medium comprise one or more of H+ ions and He+ ions.

12. The method of claim 11, wherein the one or more of the first ion medium and the second ion medium are configured to implant the one or more of the H+ ions and the He+ ions into the donor workpiece above a threshold dose.

13. The method of claim 9, wherein the split layer is defined by agglomerating the ions into a mobile gas layer associated with one or more of the first side and the second side of the donor workpiece.

14. The method of claim 9, wherein the split layer is defined by Ostwald ripening.

15. The method of claim 9, wherein smoothing the donor workpiece comprises polishing one or more of the first side and the second side of the donor workpiece.

16. A method for controlling a planarity of multiple workpieces, the method comprising:
providing a donor workpiece having an initial planarity;
presenting a first side of the donor workpiece to a first ion beam, wherein the first ion beam implants ions into the first side of the donor workpiece and deforms the donor workpiece to define a first deformation of the workpiece;
presenting a second side of the donor workpiece to a second ion beam, wherein the second ion beam implants ions into the second side of the donor workpiece and deforms the workpiece to define a second deformation of the donor workpiece, wherein the second deformation generally counteracts the first deformation of the donor workpiece to define a final planarity of the workpiece;
annealing the donor workpiece, thereby defining a split layer on one or more of the first side and the second side of the donor workpiece;
smoothing the donor workpiece to a predetermined roughness;
bonding a first receiver workpiece to the first side of the donor workpiece; and
splitting the first receiver workpiece from the donor workpiece.

17. The method of claim 16, further comprising:
bonding a second receiver workpiece to the second side of the donor workpiece; and
splitting the second receiver workpiece from the donor workpiece.

18. The method of claim 16, wherein one or more of the first ion beam and the second ion beam comprise one or more of H+ ions and He+ ions.

19. The method of claim 18, wherein the one or more of the first ion beam and the second ion beam are configured to implant the one or more of the H+ ions and the He+ ions into the donor workpiece above a threshold dose.

20. The method of claim 16, wherein the split layer is defined by agglomerating the ions into a mobile gas layer associated with one or more of the first side and the second side of the donor workpiece.
